(19) United States
(12) Patent Application Publication
(10) Pub. No.: US 2026/0360411 A1
(43) Pub. Date: Nov. 12, 2026

(54) BUFFERED COMMAND/ADDRESS INTERFACES

(71) Applicant: Rambus Inc., San Jose, CA (US)

(72) Inventor: Dongyun LEE, Sunnyvale, CA (US)

(21) Appl. No.: 19/661,205

(22) Filed: Apr. 28, 2026

Related U.S. Application Data
(60) Provisional application No. 63/874,912, filed on Sep. 3, 2025.
(60) Provisional application No. 63/800,639, filed on May 6, 2025.

(51) Int. Cl. G11C 11/408; G11C 11/4076; G11C 11/4093

(52) U.S. Cl. CPC G11C 11/4087; G11C 11/4076; G11C 11/4093

(57) ABSTRACT

In a first mode, a memory device may be configured to independently access a first set of memory arrays of the memory device in response to commands and addresses received via a first command/address (CA) interface and access a second set of memory arrays of the memory device received via a second CA interface. In a second mode, for example, the first CA interface is used to access both the first set of memory arrays and the second set of memory arrays. In this second mode, the second CA interface is used to relay the commands and addresses received via the first CA interface between the memory device and another memory device (e.g., stacked with the memory device).

### BRIEF DESCRIPTION OF THE DRAWINGS

FIGS. 1A-1B are block diagrams illustrating memory device configurations.

FIGS. 2A-2B are diagrams illustrating example stacked die command/address buffering.

FIGS. 3A-3B are diagrams illustrating an example command/address buffering configuration.

FIGS. 4A-4B are timing diagrams illustrating example command/address relay/buffering.

FIG. 5 is a flowchart illustrating a method of operating a memory device stack.

FIG. 6 is a flowchart illustrating a method of operating a memory device.

FIG. 7 is a flowchart illustrating a method of accessing a memory device.

FIG. 8 is a flowchart illustrating a method of operating stacked memory devices.

FIG. 9 is a block diagram of a processing system.

### DETAILED DESCRIPTION OF THE EMBODIMENTS

In an embodiment, in a first mode, a memory device may be configured to independently access a first set of memory arrays of the memory device in response to commands and addresses received via a first command/address (CA) interface and access a second set of memory arrays of the memory device in response to commands and addresses received via a second CA interface. In this first mode, the first CA interface and the second CA interface may be considered to be parts of different (i.e., first and second) memory channels. In a second mode, for example, the first CA interface is used to access both the first set of memory arrays and the second set of memory arrays. In this second mode, the second CA interface is used to relay the commands and addresses received via the first CA interface between the memory device and another memory device (e.g., stacked with the memory device). In a third mode, for example, the second CA interface is used to access both the first set of memory arrays and the second set of memory arrays. In a fourth mode, for example, the second CA interface is used to access both the first set of memory arrays and the second set of memory arrays, and the first CA interface is used to relay the commands and addresses received via the second CA interface between the memory device and another memory device (e.g., stacked with the memory device).

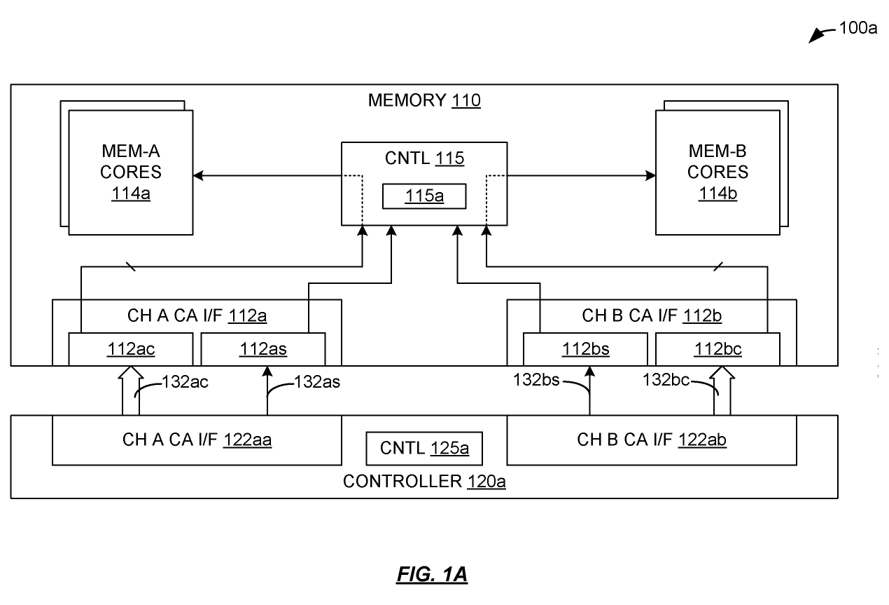

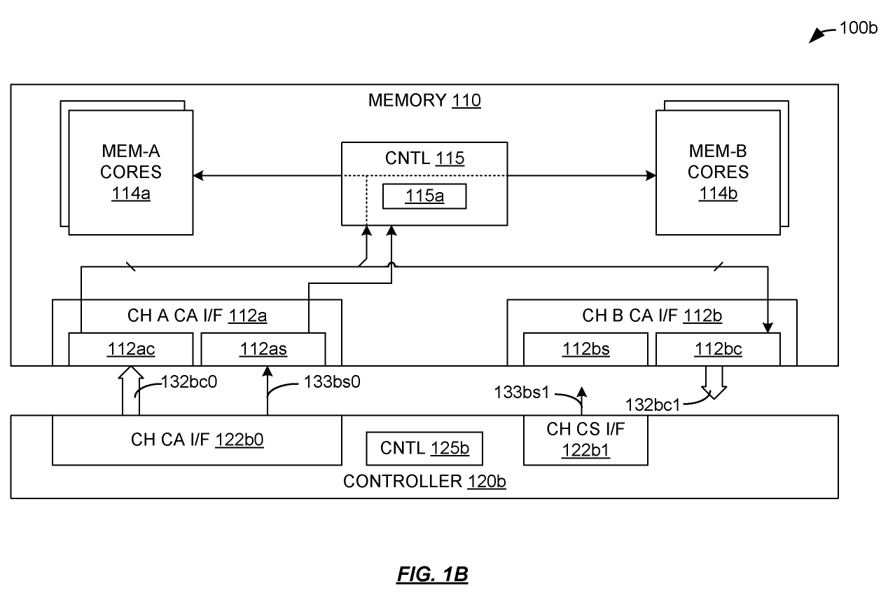

FIGS. 1A-1B are block diagrams illustrating memory device configurations. In FIGS. 1A-1B, memory device 110 and controllers 120a-120b may be one or more integrated circuit type devices, such as are commonly referred to as “chips”. Memory controllers, such as controllers 120a-120b, manage the flow of data going to and from memory devices, and/or memory components such as memory modules and/or memory device stacks (e.g., High Bandwidth memory – HBM). Memory device 110 may be a standalone device, or may be a component of a memory module such as a DIMM module used in servers. In an embodiment, memory device 110 may be a device that adheres to, or is compatible with, a dynamic random access memory (DRAM) specification. In an embodiment, memory device 110 may be, or comprise, a device that is or includes other memory device technologies and/or specifications. A memory controller can be a separate, standalone chip, or integrated into another chip. For example, a memory controller 120a-120b may be included on a single die with a microprocessor, included as a chip co-packaged with one or more microprocessor chips, included as part of a more complex integrated circuit system such as a block of a system on a chip (SOC), or be remotely coupled to one or more microprocessors via a fabric interconnect or other type of interconnect. In addition, memory controller functionality may be disposed on a separate Input/Output (I/O) die along with the transmitter/receiver circuits that interface to the memory device. Such an I/O die may include other types of I/O interfaces, as well as one or more chiplet interfaces that communicate with one or more respective CPU chiplet dies. The I/O die and CPU chiplet dies may be co-packaged together and coupled to one-another via a silicon interposer.

FIG. 1A illustrates a first example, mode/configuration for a memory device. In FIG. 1A, memory system 100a comprises memory device 110 and controller 120a. In FIG. 1A, controller 120a includes channel A command/address (CA) interface 122aa, channel B CA interface 122ab, and control circuitry 125a.

In FIGS. 1A-1B, memory device 110 comprises channel “A” command/address (CA) interface 112a, channel “B” CA interface 112b, memory channel “A” arrays (a.k.a., cores) 114a, memory channel “B” arrays 114b, and control circuitry 115. Control circuitry 115 includes mode circuitry 115a. Channel A CA interface 112a may be divided (or includes) a set of CA signals/signal interfaces 112ac and a chip select signal/signal interface 112as. Likewise, channel B CA interface 112b may be divided (or includes) a corresponding (to channel A CA interface 112a) set of CA signals/signal interfaces 112bc and a chip select signal/signal interface 112bs. As referenced herein, this first mode may also be known as “Dual channel mode”.

Channel A CA interface 112a of memory device 110 is operatively coupled with channel A CA interface 122aa of controller 120a via CA signal interfaces 112ac and CA signals 132ac. Channel A CA interface 112a of memory device 110 is also operatively coupled with channel A CA interface 122aa of controller 120a via chip select signal interface 112as and chip select signal 132as. Channel B CA interface 112b of memory device 110 is operatively coupled with channel B CA interface 122ab of controller 120a via CA signal interfaces 112bc and CA signals 132bc. Channel B CA interface 112b of memory device 110 is also operatively coupled with channel B CA interface 122ab of controller 120a via chip select signal interface 112bs and chip select signal 132bs. In FIG. 1A, memory device 110 is configured with memory arrays 114a operatively coupled with channel A CA interface 112a via control circuitry 115. Memory device 110 is also configured with memory arrays 114b operatively coupled with channel B CA interface 112b via control circuitry 115.

In the first mode, in an embodiment, each of memory arrays 114a-114b do not have any common memory arrays among them (i.e., are each nonoverlapping sets of memory arrays). Thus, in this first mode, in an embodiment, memory channel CA interfaces 112a-112b are respective operatively coupled with memory arrays 114a-114b and operate independently of each other. In other words, each memory channel CA interface 112a-112b, and operatively coupled memory arrays 114a-114b, each operate with the command, address, and data transfer functions of their respective memory channel interfaces to access respective memory arrays 114a-114b independently of the other memory channel CA interface 112a-112b and other memory arrays 114a-114b. Thus, it should be understood that when memory device 110 is in this first mode, controller 120a may, independent of accesses to memory arrays 114b, access memory arrays 114a via channel A CA interface 122aa, CA signals 132ac, chip select signal 132as, CA signal interfaces 112ac, and chip select signal interface 112as. Likewise, in this first mode, controller 120a may, independent of accesses to memory arrays 114a, access memory arrays 114b via channel B CA interface 122ab, CA signals 132bc, chip select signal 132bs, CA signal interfaces 112bc, and chip select signal interface 112bs.

FIG. 1B illustrates a second example, mode/configuration for a memory device. In FIG. 1B, memory system 100b comprises memory device 110 and controller 120b. In FIG. 1B, controller 120b includes channel CA interface 122b0, channel chip select signal interface 122b1, and control circuitry 125b. Channel A CA interface 112a of memory device 110 is operatively coupled with channel CA interface 122b0 of controller 120b via CA signal interfaces 112ac and CA signals 132bc0. Channel A CA interface 112a of memory device 110 is also operatively coupled with channel CA interface 122b0 of controller 120b via chip select signal interface 112as and chip select signals 133bs0.

As referenced herein, this second mode may also be known as one of a set of “Single channel, relay mode” (e.g., relay from A-to-B mode, and relay from B-to-A mode) – where each of these modes relays commands/addresses between a controller via a one of the CA signal interfaces 112a-112b to the other.

CA signal interface 112ac of channel A CA interface 112a is operatively coupled with CA signal interfaces 112bc of channel B CA interface 112b. Thus, in this second mode, memory device 110 is configured to communicate (e.g., relay, or buffer) data between CA signal interfaces 112ac and CA signal interfaces 112bc. Memory device 110 may be configured to communicate data between the CA signal interfaces 112ac and CA signal interfaces 112bc in order to communicate commands and addresses from controller 120b to one or more memory devices (not shown in FIGS. 1A-1B) via CA signals 132bc0 and CA signals 132bc1. One or more of these memory device coupled via CA signals 132bc1 may receive respective chip select signal(s) 133bs1 from controller 120b via channel chip select signal interface 122b1. Thus, the devices receiving CA signals 132bc0 via memory device 110 may be individually selected to respond to commands/addresses transmitted via CA signals 132bc0 and relay by memory device 110 (and/or other memory devices).

From the foregoing it should be understood that, in the second mode, in an embodiment, each of memory arrays 114a-114b share channel A CA interface 112a (and first set of CA signal interfaces 112ac, in particular) for command and address communication with controller 120b. Thus, it should be understood that when memory device 110 is in this second mode, controller 120b may not, independently of each other, access memory arrays 114a-114b.

In an embodiment, memory device 110 (and/or the other memory devices described herein) includes one or more registers (e.g., in mode circuitry 115a) to store a register value that determines modes (e.g., “single channel, relay mode”, “dual channel mode”, etc.) such that the memory device is operated and/or coupled in the manner as described and/or illustrated in the Figures. For example, this register value (i.e., mode) may be set by a memory controller (e.g., controller 120) via one or more of the channels. The Memory controller may include an interface that issues a mode register set (MRS) command, along with the register value to the memory device. The Memory device receives the MRS command and stores the register value(s) in the register(s) to set the mode. In another example, the register value(s) may also be set using serial presence detect circuitry where parameter information pertaining to the memory device, stored in a memory device (such as a serial presence detect device--SPD device) or the memory device itself is read by the memory controller or other interface. The memory controller then, based on the parameter information, sets the mode using one of the methods described herein. In another example, the register value (or mode) may be set by a signal (i.e., voltage) asserted on a pin during power-up, reset, and/or normal operating state. The memory controller may assert the voltage on the pin which is included on the memory device. In another embodiment, one or more different package or module designs can be used for the different modes. These different package or module designs may also be configured set the signal (i.e., voltage) on a pin of the memory device that determines the mode.

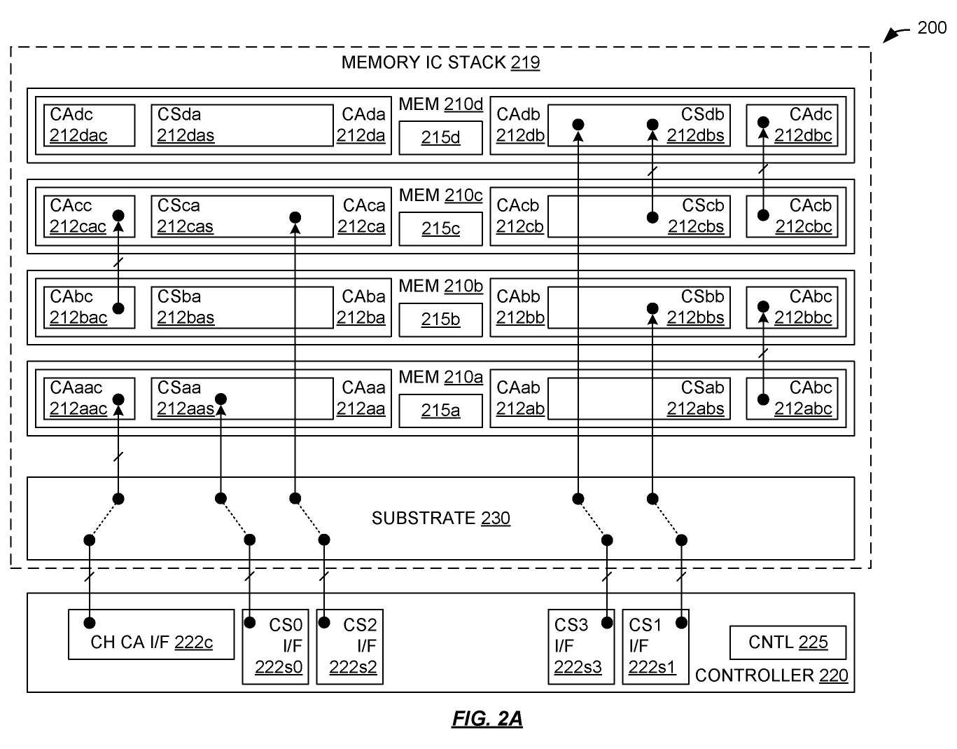

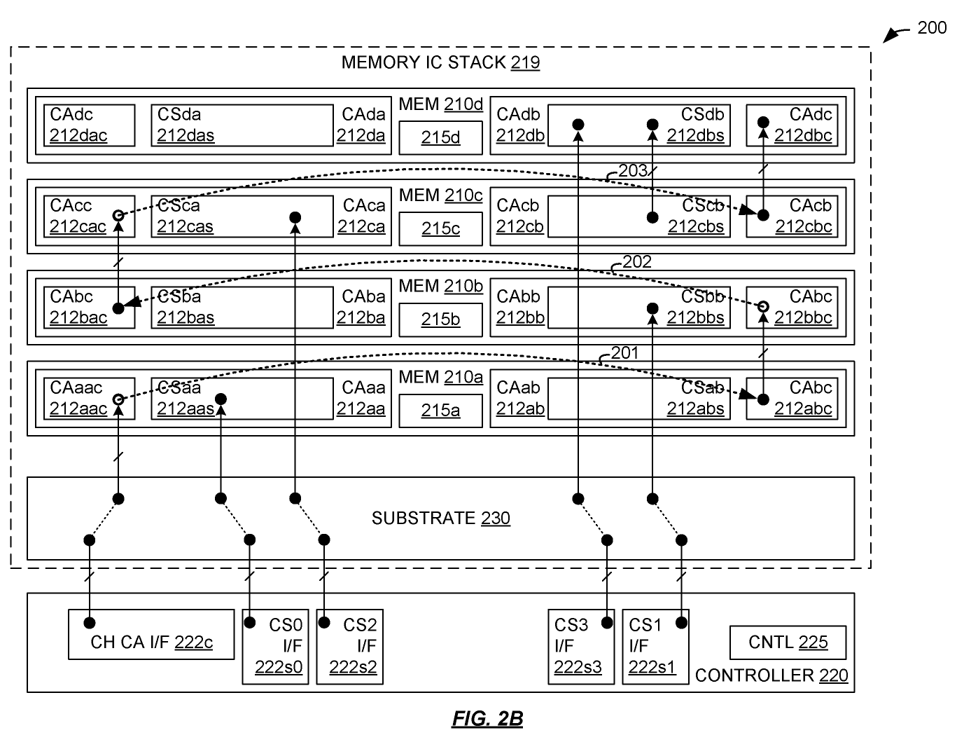

FIGS. 2A-2B are diagrams illustrating example stacked die command/address buffering. In FIGS. 2A-2B, memory system 200 comprises memory integrated circuit device (die) stack 219 and controller 220. Memory integrated circuit device stack 219 may be a packaged memory component or other type of assembly with stacked memory integrated circuits that are interconnected (e.g., by wire bonds, and/or through-silicon vias—TSVs). Memory integrated circuit device stack 219 includes memory dies 210a-210d stacked with each other and with substrate 230 (e.g., on top of substrate 230). Controller 220 includes channel CA interface 222c, chip select signal #0 interface 222s0, chip select signal #1 interface 222s1, chip select signal #2 interface 222s2, chip select signal #3 interface 222s0, and control circuitry 225.

Memory dies 210a-210d respectively include channel A CA interfaces 212aa-212da (a.k.a., CAaa-CAda), channel B CA interfaces 212ab-212db (a.k.a., CAab-CAdb), and control circuitry 215a-215d. Channel A CA interfaces 212aa-212da respectively include channel A CA signal interfaces 212aac-212dac and channel A chip select signal interfaces 212aas-212das. Channel B CA interfaces 212ab-212db respectively include CA signal interfaces 212abc-212dbc, and channel B chip select interfaces 212abs-212dbs.

Channel CA interface 222c of controller 220 is operatively connected with CA signal interfaces 212aac of channel A CA interface 212aa of memory device 210a via substrate 230. Channel CA interface 222c of controller 220 may be operatively connected with CA signal interfaces 212aac of channel A CA interface 212aa of memory device 210a using substrate 230 to memory device 210a-210d interconnections (e.g., wire bonds between substrate 230 to one or more memory devices 210a-210d) and/or memory device 210a-210d to memory device 210a-210d interconnection (e.g., wire bonds between two or more memory devices 210a-210d).

CA signal interfaces 212abc of channel B CA interface 212ab of memory device 210a are operatively connected with CA signal interfaces 212bbc of channel B CA interface 212bb of memory device 210b. CA signal interfaces 212abc of channel B CA interface 212ab of memory device 210a may be operatively connected with CA signal interfaces 212bbc of channel B CA interface 212bb of memory device 210b using memory device 210a-210d to memory device 210a-210d interconnection (e.g., wire bonds between two or more memory devices 210a-210d).

CA signal interfaces 212bac of channel A CA interface 212ba of memory device 210b are operatively connected with CA signal interfaces 212cac of channel A CA interface 212ca of memory device 210c. CA signal interfaces 212bac of channel A CA interface 212ba of memory device 210b may be operatively connected with CA signal interfaces 212cac of channel A CA interface 212ca of memory device 210c using memory device 210a-210d to memory device 210a-210d interconnection (e.g., wire bonds between two or more memory devices 210a-210d).

CA signal interfaces 212cbc of channel B CA interface 212cb of memory device 210c are operatively connected with CA signal interfaces 212dbc of channel B CA interface 212db of memory device 210d. CA signal interfaces 212cbc of channel B CA interface 212cb of memory device 210c may be operatively connected with CA signal interfaces 212dbc of channel B CA interface 212db of memory device 210d using memory device 210a-210d to memory device 210a-210d interconnection (e.g., wire bonds between two or more memory devices 210a-210d).

Chip select signal #0 interface 222s0 of controller 220 is operatively connected with chip select signal interface 212aas of channel A CA interface 212aa of memory device 210a via substrate 230. Chip select signal #0 interface 222s0 of controller 220 may be operatively connected with chip select signal interface 212aas of channel A CA interface 212aa of memory device 210a using substrate 230 to memory device 210a-210d interconnections (e.g., wire bonds between substrate 230 to one or more memory devices 210a-210d) and/or memory device 210a-210d to memory device 210a-210d interconnection (e.g., wire bonds between two or more memory devices 210a-210d).

Chip select signal #1 interface 222s1 of controller 220 is operatively connected with chip select signal interface 212bbs of channel B CA interface 212bb of memory device 210b via substrate 230. Chip select signal #1 interface 222s1 of controller 220 may be operatively connected with chip select signal interface 212bbs of channel B CA interface 212bb of memory device 210b using substrate 230 to memory device 210a-210d interconnections (e.g., wire bonds between substrate 230 to one or more memory devices 210a-210d) and/or memory device 210a-210d to memory device 210a-210d interconnection (e.g., wire bonds between two or more memory devices 210a-210d).

Chip select signal #2 interface 222s2 of controller 220 is operatively connected with chip select signal interface 212cas of channel A CA interface 212ca of memory device 210c via substrate 230. Chip select signal #2 interface 222s2 of controller 220 may be operatively connected with chip select signal interface 212cas of channel A CA interface 212ca of memory device 210c using substrate 230 to memory device 210a-210d interconnections (e.g., wire bonds between substrate 230 to one or more memory devices 210a-210d) and/or memory device 210a-210d to memory device 210a-210d interconnection (e.g., wire bonds between two or more memory devices 210a-210d).

Chip select signal #3 interface 222s3 of controller 220 is operatively connected with chip select signal interface 212dbs of channel B CA interface 212db of memory device 210d via substrate 230. Chip select signal #3 interface 222s3 of controller 220 may be operatively connected with chip select signal interface 212dbs of channel B CA interface 212db of memory device 210d using substrate 230 to memory device 210a-210d interconnections (e.g., wire bonds between substrate 230 to one or more memory devices 210a-210d) and/or memory device 210a-210d to memory device 210a-210d interconnection (e.g., wire bonds between two or more memory devices 210a-210d).

From the perspective of controller 220, memory device stack 219 may appear as a single channel, four rank, component where controller 220’s CA signals and chip select signals are connected to only a single memory devices (i.e., a signal load of one). It should also be noted that in this example, memory device 210a and memory device 210c may, for example, be configured in a “single channel, relay from A-to-B mode”. Memory device 210b and memory device 210d may, for example, be configured in a “single channel, relay from B-to-A mode”. In another example, memory device 210d may be configured in a “single channel, use B interface mode, no relay mode”.

FIG. 2B illustrates an example CA signal relay flows. In FIG. 2B, CA signals from controller 220 are relayed by memory device 210a from channel A CA signal interfaces 212aac to channel B CA signal interfaces 212abc. This is illustrated in FIG. 2B by arrow 201 running from channel A CA signal interfaces 212aac to channel B CA signal interfaces 212abc. CA signals from channel B CA interfaces 212abc of memory device 210a are relayed by memory device 210b from channel B CA signal interfaces 212bbc to channel A CA signal interfaces 212bac. This is illustrated in FIG. 2B by arrow 202 running from channel B CA signal interfaces 212bbc to channel A CA signal interfaces 212bac. CA signals from channel A CA interfaces 212bac of memory device 210b are relayed by memory device 210c from channel A CA signal interfaces 212cac to channel B CA signal interfaces 212cbc. This is illustrated in FIG. 2B by arrow 203 running from channel A CA signal interfaces 212cac to channel B CA signal interfaces 212cbc.

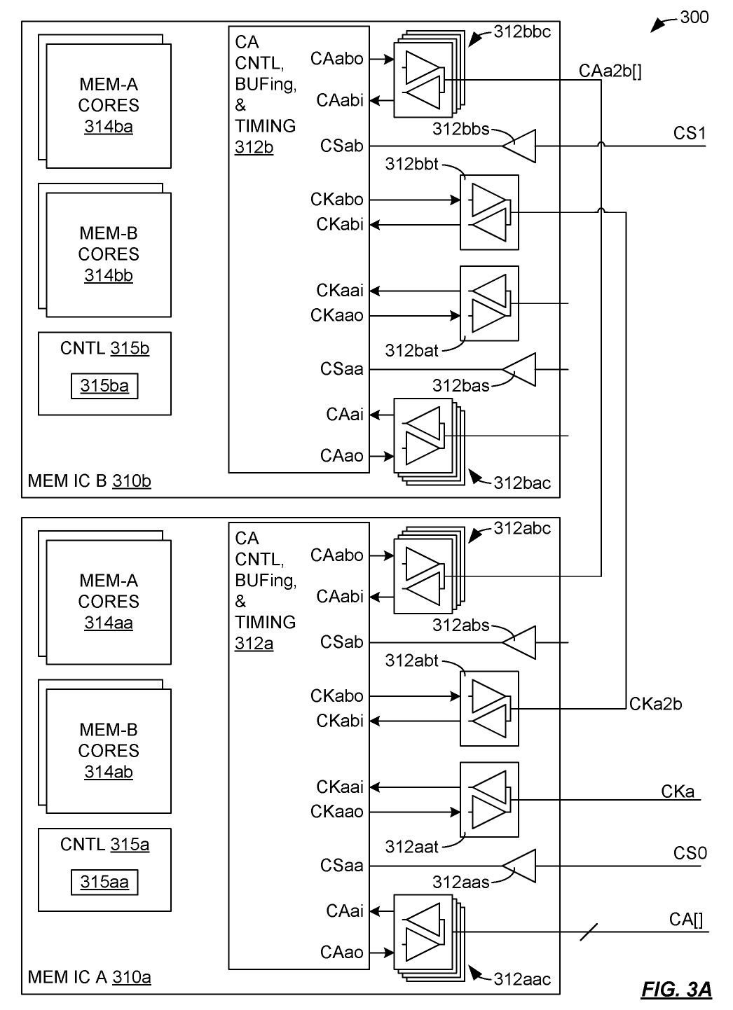

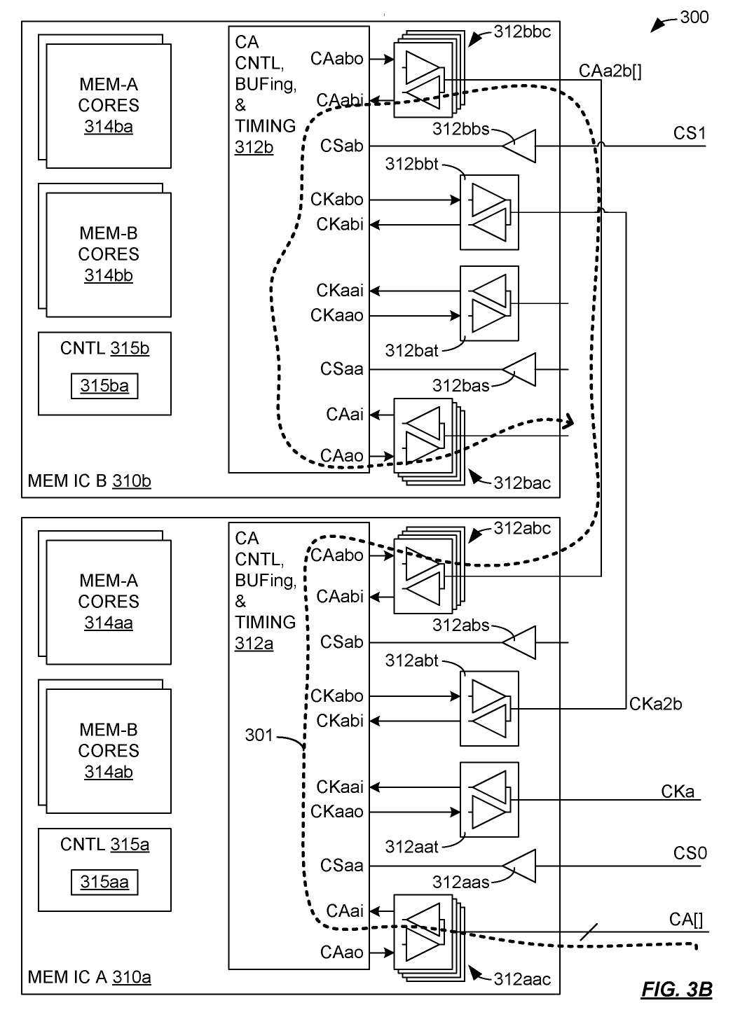

FIGS. 3A-3B are diagrams illustrating an example command/address buffering configuration. In FIGS. 3A-3B, memory system 300 comprises memory integrated circuit device 310a and memory integrated circuit device 310b. Memory integrated circuit device 310a and memory integrated circuit device 310b are, in an embodiment, stacked with each other. Memory integrated circuit device 310a includes channel A CA signal interfaces 312aac, channel B CA signal interfaces 312abc, channel A chip select signal interface 312aas, channel B chip select interface 312abs, channel A clock signal interface 312aat, channel B clock signal interface 312abt, CA control, configuration, buffering, and timing (a.k.a., CA config) circuitry 312a, channel A memory arrays 314aa, channel B memory arrays 314ab, and control circuitry 315a. Control circuitry 315a includes mode circuitry 315aa.

Memory integrated circuit device 310b includes channel A CA signal interfaces 312bac, channel B CA signal interfaces 312bbc, channel A chip select signal interface 312bas, channel B chip select interface 312bbs, , channel A clock signal interface 312bat, channel B clock signal interface 312bbt, CA control, configuration, buffering, and timing (a.k.a., CA config) circuitry 312b, channel A memory arrays 314ba, channel B memory arrays 314bb, and control circuitry 315b. Control circuitry 315b includes mode circuitry 315ba.

In FIGS. 3A-3B, channel A CA signal interfaces 312aac may be configured to operate as inputs or outputs and are operatively coupled with external CA signals CA[] (e.g., from a controller) and CA config circuitry 312a. In FIGS. 3A-3B, channel A CA signal interfaces 312aac are configured to operate as inputs. Channel B CA signal interfaces 312abc may be configured to operate as inputs or outputs and are operatively coupled with CA config circuitry 312a and internal, to the stack, CA signals CAa2b[]. In FIGS. 3A-3B, channel B CA signal interfaces 312abc are configured to operate as outputs.

Channel A chip select signal interface 312aas is operatively coupled to receive an external (e.g., from controller) chip select signal CS0 and provide it to CA config circuitry 312a. Channel B chip select interface 312abs is operatively coupled CA config circuitry 312a, but is not connected externally to memory device 310a. Channel A clock signal interface 312aat may be configured as an input or an output and is operatively coupled with CA config circuitry 312a and an external clock signal CKa (e.g., from a controller). In FIGS. 3A-3B, channel A clock signal interface 312aat is configured to operate as an input. Channel B clock signal interface 312abt may be configured as an input or an output and is operatively coupled with CA config circuitry 312a and an internal, to the stack, clock signal CKa2b. In FIGS. 3A-3B, channel B clock signal interface 312abt is configured to operate as an output.

Channel A CA signal interfaces 312bac may be configured to operate as inputs or outputs and are operatively coupled with CA config circuitry 312a, but is not connected externally to memory device 310b. Channel B CA signal interfaces 312bbc may be configured to operate as inputs or outputs and are operatively coupled with CA config circuitry 312a and internal, to the stack, CA signals CAa2b[]. In FIGS. 3A-3B, channel B CA signal interfaces 312bbc are configured to operate as inputs.

Channel A chip select signal interface 312bas is operatively coupled to CA config circuitry 312b, but is not connected externally to memory device 310b. Channel B chip select interface 312bbs is operatively coupled to receive an external (e.g., from controller) chip select signal CS1 and provide it to CA config circuitry 312b. Channel A clock signal interface 312bat may be configured as an input or an output and is operatively coupled with CA config circuitry but is not connected externally to memory device 310b. Channel B clock signal interface 312bbt may be configured as an input or an output and is operatively coupled with CA config circuitry 312b and an internal, to the stack, clock signal CKa2b. In FIGS. 3A-3B, channel B clock signal interface 312bbt is configured to operate as an input.

Memory device 310a is configured (e.g., by control circuitry 315a and using CA config circuitry 312a) to relay commands/address received by memory device 310a to memory device 310b. Memory device 310b may be configured (e.g., by control circuitry 315b and using CA config circuitry 312b) to relay commands/address received by memory device 310b to another memory device (not shown in FIGS. 3A-3B). These relays are illustrated in FIG. 3B by arrow 301 running, in order, from external CA[] signals, through channel A CA signal interfaces 312aac, through CA config circuitry 312a, through channel B CA signal interfaces 312abc, along stack internal CA signals CAa2b[], through channel B CA signal interfaces 312bbc, through CA config circuitry 312b, through channel A CA signal interfaces 312bac, and terminating outside of memory device 310b.

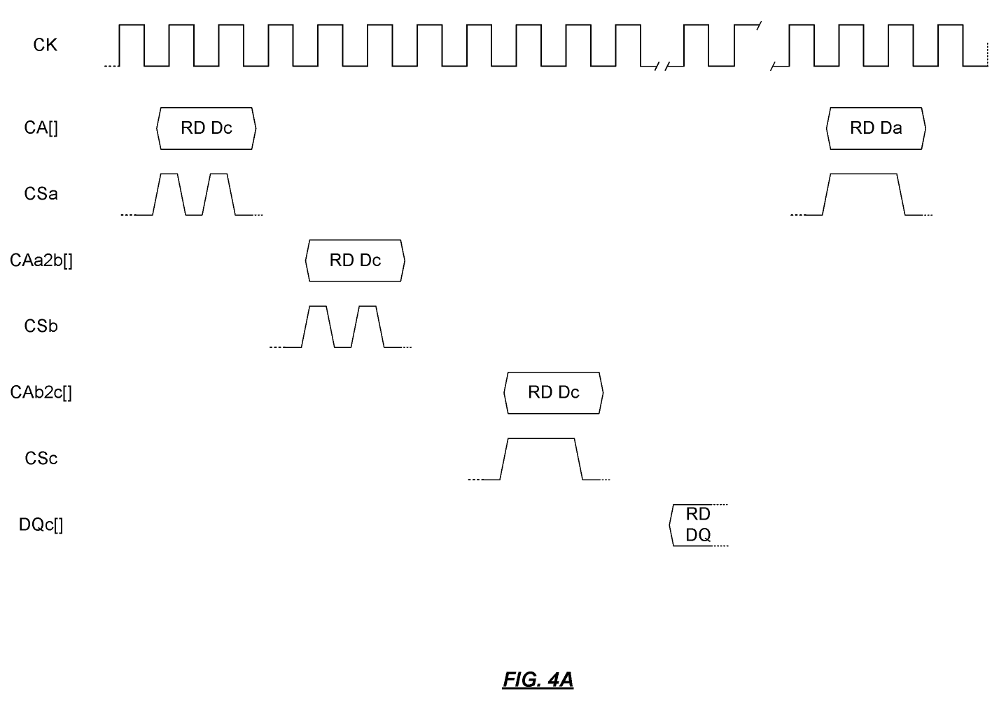

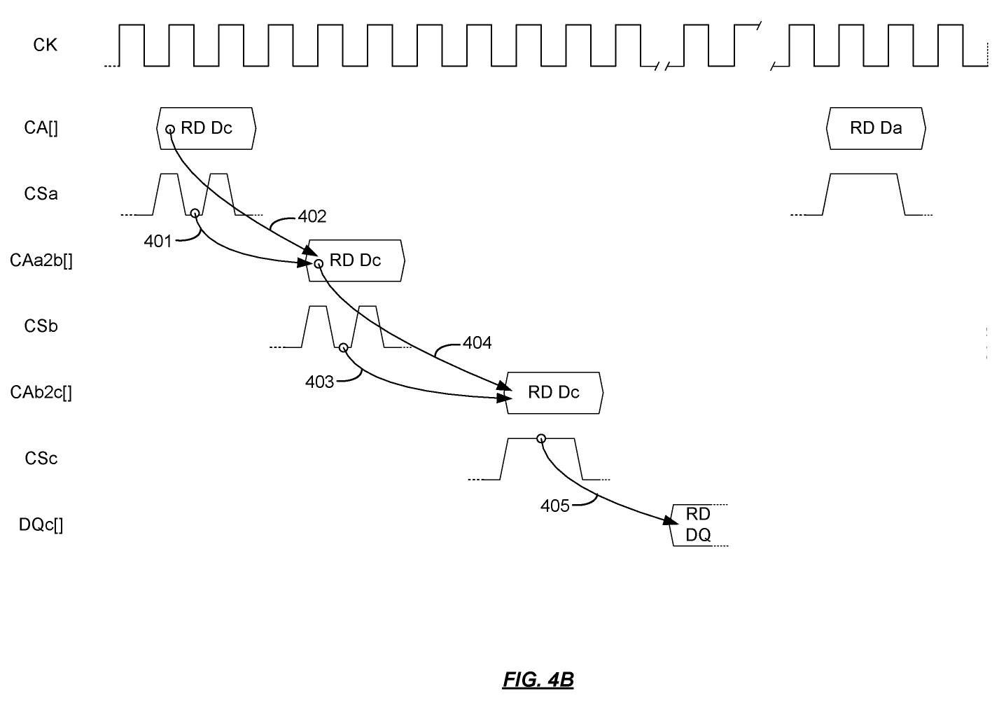

FIGS. 4A-4B are timing diagrams illustrating example command/address relay/buffering. In FIGS. 4A-4B, a first example read command (RD Dc, a.k.a., Read directed to memory device “C”) directed to memory device “C” is received by memory device A via external, to the stack, command/address signals CA[]. In this example, a memory device stack comprising memory devices A, B, and C are contemplated. Memory device A is, at least relay wise, closest to the controller and thus receives the first example read command before the other memory devices B and C. Memory device A may relay commands/addresses to memory device B. Memory device B may relay commands/addresses to memory device C.

The value of the memory device A’s chip select signal at the falling edge of the clock signal (CK) is used to determine whether memory device A is to relay the first example read command (e.g., CSa high—don’t relay, perform command; CSa low – relay the command currently being received via CA[]). Based on the signal CSa from the controller being a “low” at the first falling of the first example command, memory device A relays the first example command to memory device B via an internal, to the stack, command/address bus CAa2b[]. This is illustrated in FIG. 4B by arrow 401 running from the “low” state of CSa during the first falling edge of CK as the “RD Dc” command is being received, and arrow 402 running from the “RD Dc” command on CA[] to the “RD Dc” command on internal command address bus CAa2b[].

Similarly, the value of the memory device B’s chip select signal at the falling edge of the clock signal (CK) is used to determine whether memory device B is to relay the first example read command received from memory device A. Based on the signal CSb from the controller being a “low” at the first falling of the first example command, memory device B relays the first example command to memory device C via an internal, to the stack, command/address bus CAb2c[]. This is illustrated in FIG. 4B by arrow 403 running from the “low” state of CSb during the first falling edge of CK as the “RD Dc” command is being received by memory device B, and arrow 403 running from the “RD Dc” command on CAa2b[] to the “RD Dc” command on internal command address bus CAb2c[].

The value of the memory device C’s chip select signal at the falling edge of the clock signal (CK) is used to determine whether memory device C is to relay or perform the first example read command. Based on the signal CSc from the controller being a “high” at the first falling of the first example command, memory device C performs the first example command. This is illustrated in FIG. 4B by arrow 405 running from the “high” state of CSc during the first falling edge of CK as the “RD Dc” command is being received to the “RD DQ” data illustrated on the DQ lines of memory device C DQc[].

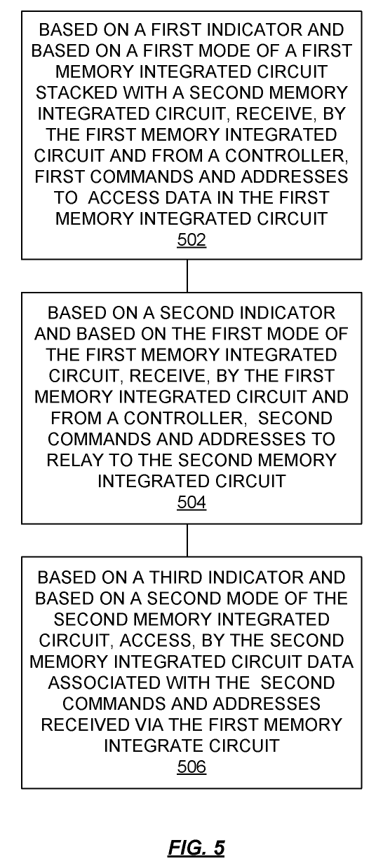

FIG. 5 is a flowchart illustrating a method of operating a memory device stack. One or more of the steps illustrated in FIG. 5 may be performed by, for example, system 100a, system 100b, system 200, system 300, and/or their components. Based on a first indicator and based on a first mode of a first memory integrated circuit stacked with a second memory integrated circuit, and by the first memory integrated circuit and from a controller, first commands and addresses to access data in the first memory integrated circuit are received (502). For example, memory device 310a, when not in a two-channel mode, may receive, from a controller, a chip select signal and/or associated read command that indicates the read command is to access data in one or more of memory cores 314aa-314ab.

Based on a second indicator and based on the first mode of the first memory integrated circuit, and by the first memory integrated circuit and from a controller, second commands and addresses to relay to the second memory integrated circuit are received (504). For example, memory device 310a, when not in a two-channel mode, may receive, from the controller, a chip select signal and/or associated read command that indicates the read command is to relay the read command to memory device 310b. Based on a third indicator and based on a second mode of the second memory integrated circuit, and by the second memory integrated circuit, data associated with the second commands and addresses received via the first memory integrate circuit is accessed (506). For example, memory device 310b, when not in a two-channel mode, may receive, from the controller, a chip select signal that indicates the read received from memory device 310a is to be performed to access data in one or more of memory cores 314ba-314bb.

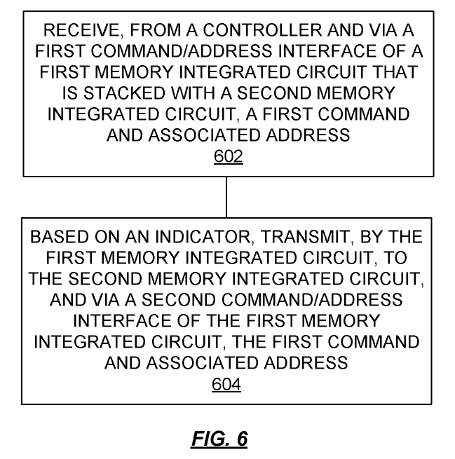

FIG. 6 is a flowchart illustrating a method of operating a memory device. One or more of the steps illustrated in FIG. 6 may be performed by, for example, system 100a, system 100b, system 200, system 300, and/or their components. From a controller and via a first command/address interface of a first memory integrated circuit that is stacked with a second memory integrated circuit, a first command and associated address are received (602). For example, memory device 310a may receive, from a controller and via CA[] signals and CA interfaces 312aac, a first command and associated address.

Based on an indicator, by the first memory integrated circuit, and via a second command/address interface of the first memory integrated circuit, the first command and associated address are transmitted to the second memory integrated circuit (604). For example, memory device 310a may, based on a chip select received from a controller via channel A chip select signal interface 312aas, transmit, via channel B CA interfaces 312abc the first command and associated address received via CA interfaces 312aac.

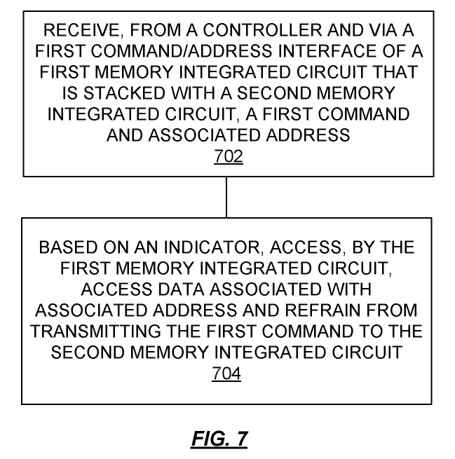

FIG. 7 is a flowchart illustrating a method of accessing a memory device. One or more of the steps illustrated in FIG. 7 may be performed by, for example, system 100a, system 100b, system 200, system 300, and/or their components. From a controller and via a first command/address interface of a first memory integrated circuit that is stacked with a second memory integrated circuit, a first command and associated address are received (702). For example, memory device 310a may receive, from a controller and via CA[] signals and CA interfaces 312aac, a first command and associated address.

Based on an indicator and by the first memory integrated circuit, data associated with associated address is accesses and the first command is not transmitted to the second memory integrated circuit (704). For example, memory device 310a may, based on a chip select received from a controller via channel A chip select signal interface 312aas, access data from memory arrays 314aa-314ab that are associated address with the first command and address that were received via CA interfaces 312aac.

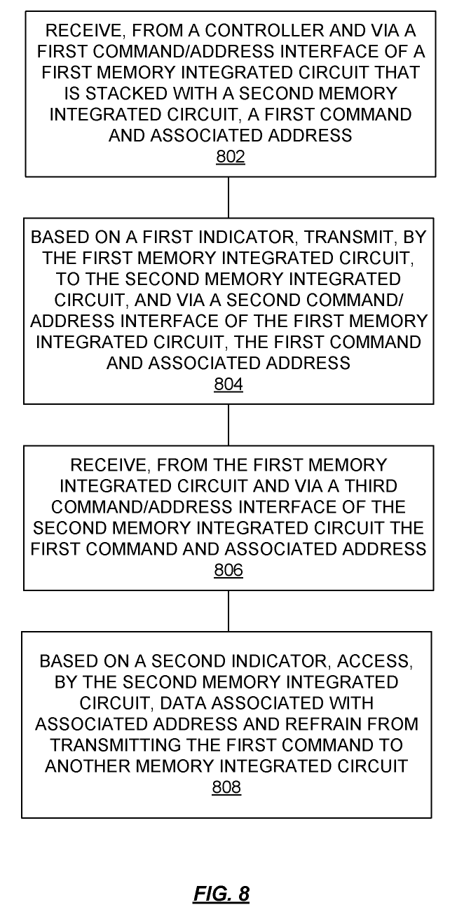

FIG. 8 is a flowchart illustrating a method of operating stacked memory devices. One or more of the steps illustrated in FIG. 8 may be performed by, for example, system 100a, system 100b, system 200, system 300, and/or their components. From a controller and via a first command/address interface of a first memory integrated circuit that is stacked with a second memory integrated circuit, a first command and associated address are received (802). For example, memory device 310a may receive, from a controller and via CA[] signals and CA interfaces 312aac, a first command and associated address.

Based on an indicator, by the first memory integrated circuit, and via a second command/address interface of the first memory integrated circuit, the first command and associated address are transmitted to the second memory integrated circuit (804). For example, memory device 310a may, based on a chip select received from a controller via channel A chip select signal interface 312aas, transmit, via channel B CA interfaces 312abc the first command and associated address received via CA interfaces 312aac. From the first memory integrated circuit and via a third command/address interface of the second memory integrated circuit, the first command and associated address are received (806). For example, memory device 310b may receive, from memory device 310a and via CA interfaces 310bac, the first command and associated address (806).

Based on a second indicator and by the second memory integrated circuit, data associated with associated address is accessed and the first command is not transmitted to another memory integrated circuit (808). For example, memory device 310b may, based on a chip select received from the controller via channel B chip select signal interface 312bbs, access data from memory arrays 314ba-314bb that are associated address with the first command and address that were received via CA interfaces 312bac.

The methods, systems and devices described above may be implemented in computer systems, or stored by computer systems. The methods described above may also be stored on a non-transitory computer readable medium. Devices, circuits, and systems described herein may be implemented using computer-aided design tools available in the art, and embodied by computer-readable files containing software descriptions of such circuits. This includes, but is not limited to one or more elements of system 100a, system 100b, system 200, and/or system 300, and their components. These software descriptions may be: behavioral, register transfer, logic component, transistor, and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3-1/2 inch floppy media, CDs, DVDs, and so on.

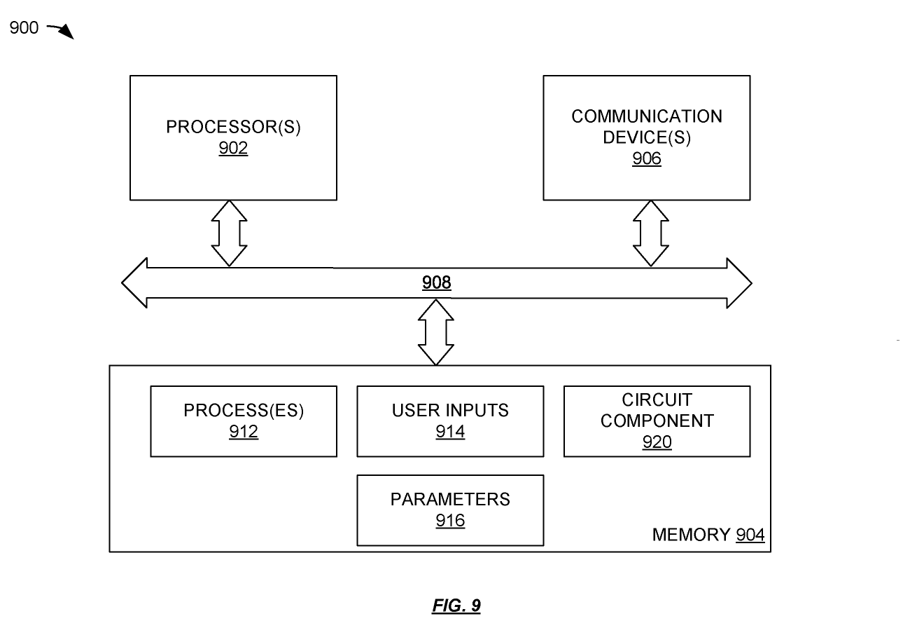

FIG. 9 is a block diagram illustrating one embodiment of a processing system 900 for including, processing, or generating, a representation of a circuit component 920. Processing system 900 includes one or more processors 902, a memory 904, and one or more communications devices 906. Processors 902, memory 904, and communications devices 906 communicate using any suitable type, number, and/or configuration of wired and/or wireless connections 908.

Processors 902 execute instructions of one or more processes 912 stored in a memory 904 to process and/or generate circuit component 920 responsive to user inputs 914 and parameters 916. Processes 912 may be any suitable electronic design automation (EDA) tool or portion thereof used to design, simulate, analyze, and/or verify electronic circuitry and/or generate photomasks for electronic circuitry. Representation 920 includes data that describes all or portions of system 100a, system 100b, system 200, and/or system 300, and their components, as shown in the Figures.

Representation 920 may include one or more of behavioral, register transfer, logic component, transistor, and layout geometry-level descriptions. Moreover, representation 920 may be stored on storage media or communicated by carrier waves.

Data formats in which representation 920 may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email.

User inputs 914 may comprise input parameters from a keyboard, mouse, voice recognition interface, microphone and speakers, graphical display, touch screen, or other type of user interface device. This user interface may be distributed among multiple interface devices. Parameters 916 may include specifications and/or characteristics that are input to help define representation 920. For example, parameters 916 may include information that defines device types (e.g., NFET, PFET, etc.), topology (e.g., block diagrams, circuit descriptions, schematics, etc.), and/or device descriptions (e.g., device properties, device dimensions, power supply voltages, simulation temperatures, simulation models, etc.).

Memory 904 includes any suitable type, number, and/or configuration of non-transitory computer-readable storage media that stores processes 912, user inputs 914, parameters 916, and circuit component 920.

Communications devices 906 include any suitable type, number, and/or configuration of wired and/or wireless devices that transmit information from processing system 900 to another processing or storage system (not shown) and/or receive information from another processing or storage system (not shown). For example, communications devices 906 may transmit circuit component 920 to another system. Communications devices 906 may receive processes 912, user inputs 914, parameters 916, and/or circuit component 920 and cause processes 912, user inputs 914, parameters 916, and/or circuit component 920 to be stored in memory 904.

Implementations discussed herein include, but are not limited to, the following examples:
Example 1: A memory device, comprising: a first set of memory arrays; a second set of memory arrays that does not overlap with the first set of memory arrays; a first set of command/address (CA) signal interfaces to, in a first mode, be used to receive commands and addresses that access the first set of memory arrays; a second set of CA signal interfaces to, in the first mode, be used to receive commands and addresses that access the second set of memory arrays; the first set of CA signal interfaces to, in a second mode and based on a first indicator, receive commands and addresses that access the first set of memory arrays and the second set of memory array; and the second set of CA signal interfaces to, in the second mode, transmit commands and addresses received via the first set of CA signal interfaces to another memory device that is stacked with the memory device.
Example 2: The memory device of example 1, wherein whether the second set of CA signal interfaces is to transmit commands and addresses received via the first set of CA signal interfaces is based on a second indicator.
Example 3: The memory device of example 2, wherein the first indicator and the second indicator are to be received via a chip select signal interface associated with the first set of CA signal interfaces.
Example 4: The memory device of example 2, wherein the first indicator and the second indicator are to be received via the first set of CA signal interfaces.
Example 5: The memory device of example 1, further comprising: CA decoding circuitry to, in the second mode and based on the first indicator, decode commands and addresses that access the first set of memory arrays and the second set of memory arrays.
Example 6: The memory device of example 5, wherein, whether CA decoding circuitry is to decode addresses that access the first set of memory arrays and the second set of memory arrays is based on a second indicator.
Example 7: The memory device of example 6, wherein the first indicator and the second indicator are to be received via a chip select signal interface associated with the first set of CA signal interfaces.
Example 8: A memory component, comprising: a first memory integrated circuit die comprising: a first set of memory arrays and a second set of memory arrays, the first set of memory arrays and the second set of memory arrays being disjoint sets of memory arrays, a first set of command/address (CA) signal interfaces, and a second set of CA signal interfaces, where the first set of CA signal interfaces and the second set of CA signal interfaces are disjoint sets; a second memory integrated circuit die coupled with, and stacked with, the first memory integrated circuit, the second memory integrated circuit die comprising: a third set of memory arrays and a fourth set of memory arrays, the third set of memory arrays and the fourth set of memory arrays being disjoint sets of memory arrays; a third set of CA signal interfaces; the first memory integrated circuit die having a first mode where the first set of CA signal interfaces are used to access the first set of memory arrays and the second set of CA signal interfaces are used to access the second set of memory arrays; the first memory integrated circuit die to, based on a second mode and a first indicator, use the first set of CA signal interfaces to access the first set of memory arrays and the second set of memory arrays; and the first memory integrated circuit die to also, based on the second mode and a second indicator, communicate commands and addresses received via the first set of CA signal interfaces with the third set of CA signal interfaces and via the second set of CA signal interfaces to access the third set of memory arrays and the fourth set of memory arrays.
Example 9: The memory component of example 8, wherein the first memory integrated circuit is to, based on the first indicator, not communicate commands and addresses received via the first set of CA signal interfaces with the third set of CA signal interfaces via the second set of CA signal interfaces.
Example 10: The memory component of example 9, wherein the first indicator is to be received via a chip select signal interface associated with the first set of CA signal interfaces.
Example 11: The memory component of example 10, wherein the second indicator is to be received via the chip select signal interface associated with the first set of CA signal interfaces.
Example 12: The memory component of example 9, wherein the first indicator and the second indicator are to be received via the first set of CA signal interfaces.
Example 13: The memory component of example 9, wherein the first memory integrated circuit die further comprises: CA decoding circuitry that is to, based on the second mode and the first indicator, operate to perform accesses of the first set of memory arrays and the second set of memory arrays.
Example 14: The memory component of example 13, wherein, based on the second mode and the second indicator, the CA decoding circuitry is to not operate in response to commands and addresses received via the first set of CA signal interfaces and communicated with the third set of CA signal interfaces via the second set of CA signal interfaces.
Example 15: A memory component, comprising: a first memory integrated circuit die having a first set of memory arrays and a second set of memory arrays, the first set of memory arrays and the second set of memory arrays being disjoint sets of memory arrays; a second memory integrated circuit die electrically coupled with, and stacked with, the first memory integrated circuit die, and having a third set of memory arrays and a fourth set of memory arrays, the third set of memory arrays and the fourth set of memory arrays being disjoint sets of memory arrays; the first memory integrated circuit die having a first mode where a first plurality of command/address (CA) interface circuits are used to access the first set of memory arrays and second plurality of CA interface circuits are used to access the second set of memory arrays; and the first memory integrated circuit die to be configured, based on a second mode, to relay commands and addresses received via the first plurality of CA interface circuits to the second plurality of CA interface circuits for transmission to the second memory integrated circuit die for accesses, by a controller, of the third set of memory arrays and the fourth set of memory arrays.
Example16: The memory component of example 15, wherein the first memory integrated circuit die further comprises: relay control circuitry to, based on a first indicator, determine whether to relay a first command and address received via the first plurality of CA interface circuits to the second plurality of CA interface circuits for transmission to the second memory integrated circuit.
Example 17: The memory component of example 16, wherein the first indicator is to be received a chip select interface circuit associated with the first plurality of CA interface circuits.
Example 18: The memory component of example 16, wherein the first command and address comprise the first indicator.
Example 19: The memory component of example 16, wherein the first plurality of CA interface circuits includes a first clock signal interface circuit and the second plurality of CA interface circuits includes a second clock signal interface circuit and a clock signal received via the first clock signal interface circuit is to be relayed, based on the second mode, to the second memory integrated circuit via the second clock signal interface circuit.
Example 20: The memory component of example 16, wherein a first clock signal is to be provided by the controller to a first clock signal interface circuit of the first memory integrated circuit die and a second clock signal is to be provided by the controller to a second clock signal interface circuit of the second memory integrated circuit die.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A memory device, comprising:
a first set of memory arrays;
a second set of memory arrays that does not overlap with the first set of memory arrays;
a first set of command/address (CA) signal interfaces to, in a first mode, be used to receive commands and addresses that access the first set of memory arrays;
a second set of CA signal interfaces to, in the first mode, be used to receive commands and addresses that access the second set of memory arrays;
the first set of CA signal interfaces to, in a second mode and based on a first indicator, receive commands and addresses that access the first set of memory arrays and the second set of memory array; and
the second set of CA signal interfaces to, in the second mode, transmit commands and addresses received via the first set of CA signal interfaces to another memory device that is stacked with the memory device.

2. The memory device of claim 1, wherein whether the second set of CA signal interfaces is to transmit commands and addresses received via the first set of CA signal interfaces is based on a second indicator.

3. The memory device of claim 2, wherein the first indicator and the second indicator are to be received via a chip select signal interface associated with the first set of CA signal interfaces.

4. The memory device of claim 2, wherein the first indicator and the second indicator are to be received via the first set of CA signal interfaces.

5. The memory device of claim 1, further comprising:
CA decoding circuitry to, in the second mode and based on the first indicator, decode commands and addresses that access the first set of memory arrays and the second set of memory arrays.

6. The memory device of claim 5, wherein, whether CA decoding circuitry is to decode addresses that access the first set of memory arrays and the second set of memory arrays is based on a second indicator.

7. The memory device of claim 6, wherein the first indicator and the second indicator are to be received via a chip select signal interface associated with the first set of CA signal interfaces.

8. A memory component, comprising:
a first memory integrated circuit die comprising:
a first set of memory arrays and a second set of memory arrays, the first set of memory arrays and the second set of memory arrays being disjoint sets of memory arrays,
a first set of command/address (CA) signal interfaces, and
a second set of CA signal interfaces, where the first set of CA signal interfaces and the second set of CA signal interfaces are disjoint sets;
a second memory integrated circuit die coupled with, and stacked with, the first memory integrated circuit, the second memory integrated circuit die comprising:
a third set of memory arrays and a fourth set of memory arrays, the third set of memory arrays and the fourth set of memory arrays being disjoint sets of memory arrays;
a third set of CA signal interfaces;
the first memory integrated circuit die having a first mode where the first set of CA signal interfaces are used to access the first set of memory arrays and the second set of CA signal interfaces are used to access the second set of memory arrays;
the first memory integrated circuit die to, based on a second mode and a first indicator, use the first set of CA signal interfaces to access the first set of memory arrays and the second set of memory arrays; and
the first memory integrated circuit die to also, based on the second mode and a second indicator, communicate commands and addresses received via the first set of CA signal interfaces with the third set of CA signal interfaces and via the second set of CA signal interfaces to access the third set of memory arrays and the fourth set of memory arrays.

9. The memory component of claim 8, wherein the first memory integrated circuit is to, based on the first indicator, not communicate commands and addresses received via the first set of CA signal interfaces with the third set of CA signal interfaces via the second set of CA signal interfaces.

10. The memory component of claim 9, wherein the first indicator is to be received via a chip select signal interface associated with the first set of CA signal interfaces.

11. The memory component of claim 10, wherein the second indicator is to be received via the chip select signal interface associated with the first set of CA signal interfaces.

12. The memory component of claim 9, wherein the first indicator and the second indicator are to be received via the first set of CA signal interfaces.

13. The memory component of claim 9, wherein the first memory integrated circuit die further comprises:
CA decoding circuitry that is to, based on the second mode and the first indicator, operate to perform accesses of the first set of memory arrays and the second set of memory arrays.

14. The memory component of claim 13, wherein, based on the second mode and the second indicator, the CA decoding circuitry is to not operate in response to commands and addresses received via the first set of CA signal interfaces and communicated with the third set of CA signal interfaces via the second set of CA signal interfaces.

15. A memory component, comprising:
a first memory integrated circuit die having a first set of memory arrays and a second set of memory arrays, the first set of memory arrays and the second set of memory arrays being disjoint sets of memory arrays;
a second memory integrated circuit die electrically coupled with, and stacked with, the first memory integrated circuit die, and having a third set of memory arrays and a fourth set of memory arrays, the third set of memory arrays and the fourth set of memory arrays being disjoint sets of memory arrays;
the first memory integrated circuit die having a first mode where a first plurality of command/address (CA) interface circuits are used to access the first set of memory arrays and second plurality of CA interface circuits are used to access the second set of memory arrays; and
the first memory integrated circuit die to be configured, based on a second mode, to relay commands and addresses received via the first plurality of CA interface circuits to the second plurality of CA interface circuits for transmission to the second memory integrated circuit die for accesses, by a controller, of the third set of memory arrays and the fourth set of memory arrays.

16. The memory component of claim 15, wherein the first memory integrated circuit die further comprises:
relay control circuitry to, based on a first indicator, determine whether to relay a first command and address received via the first plurality of CA interface circuits to the second plurality of CA interface circuits for transmission to the second memory integrated circuit.

17. The memory component of claim 16, wherein the first indicator is to be received a chip select interface circuit associated with the first plurality of CA interface circuits.

18. The memory component of claim 16, wherein the first command and address comprise the first indicator.

19. The memory component of claim 16, wherein the first plurality of CA interface circuits includes a first clock signal interface circuit and the second plurality of CA interface circuits includes a second clock signal interface circuit and a clock signal received via the first clock signal interface circuit is to be relayed, based on the second mode, to the second memory integrated circuit via the second clock signal interface circuit.

20. The memory component of claim 16, wherein a first clock signal is to be provided by the controller to a first clock signal interface circuit of the first memory integrated circuit die and a second clock signal is to be provided by the controller to a second clock signal interface circuit of the second memory integrated circuit die.
